(19) United States
(12) Patent Application Publication
(10) Pub. No.: US 2026/0164554 A1
(43) Pub. Date: Jun. 11, 2026

(54) PRINTED CIRCUIT BOARD

(71) Applicant: SAMSUNG ELECTRO-MECHANICS CO., LTD., Suwon-si (KR)

(72) Inventor: Jae Woong CHOI, Suwon-si (KR)

(73) Assignee: SAMSUNG ELECTRO-MECHANICS CO., LTD., Suwon-si (KR)

(21) Appl. No.: 19/179,535

(22) Filed: Apr. 15, 2025

(30) Foreign Application Priority Data
Sep. 6, 2024 (KR) 10-2024-0121211

(51) Int. Cl. H05K 1/11; H05K 1/03; H05K 1/183

(52) U.S. Cl. CPC H05K 1/116; H05K 1/0306; H05K 1/183; H05K 2201/09827

(57) ABSTRACT

A glass layer; a cavity penetrating a portion of the glass layer from an upper surface of the glass layer; an interconnect unit including at least a portion disposed in the cavity and including a polymer layer and a plurality of first through-vias each penetrating the polymer layer; and a plurality of second through-vias each penetrating the glass layer from a lower surface of the glass layer to a bottom surface of the cavity, wherein the plurality of first through-vias are connected to the plurality of second through-vias, respectively.

### CROSS-REFERENCE TO RELATED APPLICATIONS

This application claims the benefit of priority to Korean Patent Application No. 10-2024-0121211 filed on Sep. 6, 2024 in the Korean Intellectual Property Office, the disclosure of which is incorporated herein by reference in its entirety.

### TECHNICAL FIELD

The present disclosure relates to a printed circuit board.

### BACKGROUND

In order to implement high performance in products for high performance computing (HPC) such as a server, artificial intelligence (AI), and network, a body size of a package has increased and the number of layers has also increased. In this case, warpage control of the substrate may be difficult, and accordingly, a core may be configured to have an increased thickness, but when a core has an increased thickness, a signal path or a power path may also increase. Accordingly, signal and power characteristics may be degraded.

### SUMMARY

An aspect of the present disclosure is to provide a printed circuit board which may have a body having a relatively large, may easily perform control warpage, and may improve signal and/or power characteristics by improving signal and/or power paths.

An aspect of the present disclosure is to form an electrical path having a fine pitch and a fine size in one region of a glass core by forming a cavity having a blind shape in the glass core, disposing an interconnect unit including a first through-via having a fine pitch in the cavity, and forming a second through-via penetrating the glass core on a lower side of the cavity having a fine pitch and connected to the first through-via.

According to an embodiment, a printed circuit board includes a glass layer; a cavity penetrating a portion of the glass layer from an upper surface of the glass layer; an interconnect unit including at least a portion disposed in the cavity and including a polymer layer and a plurality of first through-vias each penetrating the polymer layer; and a plurality of second through-vias each penetrating the glass layer from a lower surface of the glass layer to a bottom surface of the cavity, wherein the plurality of first through-vias are connected to the plurality of second through-vias, respectively.

According to an embodiment, a printed circuit board includes a glass core having a blind cavity; an interconnect unit having at least a portion disposed in the blind cavity; a plurality of second through-vias each penetrating the glass core in a region overlapping the blind cavity when the glass core is viewed from above; a plurality of third through-vias each penetrating the glass core in a region spaced apart from the blind cavity when the glass core is viewed from above; a first built-up structure disposed on an upper side of the glass core and including a plurality of first wiring layers; and a second built-up structure disposed on a lower side of the glass core and including a plurality of second wiring layers.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating an example of an electronic device system;

FIG. 2 is a perspective diagram illustrating an example of an electronic device;

FIG. 3 is a process diagram illustrating the printed circuit board illustrated in FIG. 2;

FIG. 4 is a cross-sectional diagram illustrating a modified example of the printed circuit board illustrated in FIG. 2;

FIG. 5 is a cross-sectional diagram illustrating another example of a printed circuit board according an embodiment;

FIG. 6 is a cross-sectional diagram illustrating a modified example of the printed circuit board illustrated in FIG. 5;

FIG. 7 is a cross-sectional diagram illustrating another example of a printed circuit board according an embodiment; and

FIG. 8 is a cross-sectional diagram illustrating a modified example of the printed circuit board illustrated in FIG. 7.

### DETAILED DESCRIPTION

Hereinafter, embodiments of the present disclosure will be described as follows with reference to the attached drawings. Some elements may be exaggerated, omitted or briefly illustrated, and the sizes of the elements do not necessarily reflect the actual sizes of these elements

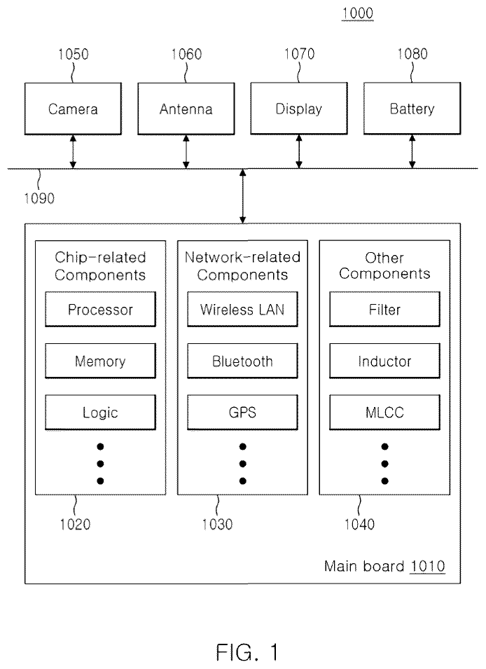

FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access + (HSPA+), high speed downlink packet access + (HSDPA+), high speed uplink packet access + (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

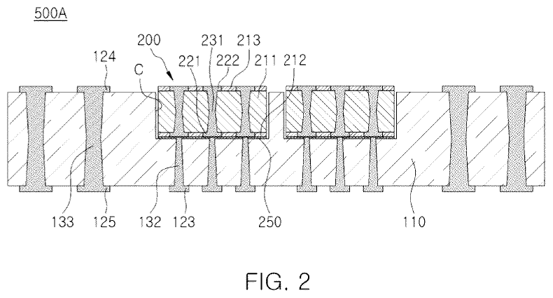

FIG. 2 is a perspective diagram illustrating an example of an electronic device.

Referring to the drawing, a printed circuit board 500A according to an example may include a glass layer 110, a cavity C penetrating a portion of the glass layer 110 from an upper surface of the glass layer 110, an interconnect unit 200 having at least a portion disposed in the cavity C and including a plurality of first through-vias 231, a plurality of second through-vias 132 each penetrating the glass layer 110 from a lower surface of the glass layer 110 to a bottom surface of the cavity C. The plurality of first through-vias 231 may be connected to a plurality of second through-vias 132, respectively.

Since the printed circuit board 500A includes the glass layer 110 as described above, it may be easy to apply to a body having a relatively large size, and warpage may be may be effectively controlled. Also, the interconnect unit 200 including a plurality of first through-vias 231 may be disposed in cavity C, and the plurality of second through-vias 132, connected to the plurality of first through-vias 231, respectively, may be disposed on a lower side of cavity C. In this case, the plurality of first and second through-vias 231 and 132 may be formed with a fine pitch and fine size, such that an electrical path having a fine pitch and a fine size may be provided in one region even when the glass layer 110 has an increased thickness. Accordingly, a signal and/or power path transmitted from a semiconductor chip mounted on the printed circuit board 500A may be improved. Accordingly, signal and/or power characteristics may be improved. Also, since a separately manufactured interconnect unit 200 is used, yield may also be improved.

The cavity C may have a blind shape penetrating a portion of the glass layer 110 from an upper surface of the glass layer 110 toward a lower surface. For example, the cavity C may be a blind cavity C. The interconnect unit 200 may be attached to a bottom surface of the blind cavity C via the adhesive layer 250. In this case, the plurality of second through-vias 132 may further penetrate the adhesive layer 250, and accordingly, the plurality of first through-vias 231 may be easily connected to each other. For example, the plurality of second through-vias 132 may be formed in via-holes collectively penetrating the glass layer 110 and the adhesive layer 250 from a lower surface of the glass layer 110 to the interconnect unit 200, and may have a substantially tapered shape in which a width on a cross-section of a lower end is wider than a width on a cross-section of an upper end.

A plurality of the cavities C and a plurality of the interconnect units 200 may be provided. For example, the plurality of cavities C may be spaced apart from each other in the glass layer 110, and the plurality of interconnect units 200 may be disposed in the plurality of cavities C, respectively. Also, the plurality of second through-vias 132 may be disposed on a lower side of each of the plurality of cavities C. However, an embodiment thereof is not limited thereto, and if desired, the plurality of interconnect units 200 may be disposed in at least one of the blind cavity C.

The interconnect unit 200 may include a polymer layer 211 and a plurality of first through-vias 231 each penetrating the polymer layer 211. For example, the interconnect unit 200 may be an organic substrate. Accordingly, the manufacturing process may be performed in a simplified manner, and the cost may be effectively reduced. Also, since the polymer layer 211 may have a relatively small thickness, a fine pitch and a fine size of the plurality of first through-vias 231 may be easily implemented.

The interconnect unit 200 may further include a plurality of first pads 221 disposed on a lower side of the polymer layer 211 and connected to lower sides of the first through-vias 231, respectively, a plurality of second pads 222 disposed on an upper side of the polymer layer 211 and connected to upper sides of the first through-vias 231, respectively, a first passivation layer 212 disposed on a lower side of the polymer layer 211 and covering at least a portion of the plurality of first pads 221, and/or a second passivation layer 213 disposed on an upper side of the polymer layer 211 and covering at least a portion of the plurality of second pads 222. For example, the interconnect unit 200 may be a two-layer organic substrate, but an embodiment thereof is not limited thereto. The plurality of second through-vias 132 may be connected to the plurality of first through-vias 231 through the plurality of first pads 221, respectively.

The printed circuit board 500A may further include a plurality of third through-vias 133 penetrating between the upper surface and the lower surface of the glass layer 110 in a region spaced apart from a region in which the cavity C is disposed. The plurality of third through-vias 133 may be a through glass via (TGV) corresponding to the entire thickness of the glass layer 110. In this case, a minimum pitch between the plurality of first through-vias 231 and a minimum pitch between the plurality of second through-vias 132 may be smaller than a minimum pitch between the plurality of third through-vias 133. Also, a minimum diameter of each of the plurality of first through-vias 231 and a minimum diameter of each of the plurality of second through-vias 132 may be smaller than a minimum diameter of each of the plurality of third through-vias 133. Accordingly, an electrical path having a fine pitch and a fine size may be easily provided in one region of the glass layer 110.

A pitch between the plurality of through-vias may be a distance between central lines of each of two adjacent through-vias, and the minimum pitch between the plurality of through-vias may be a minimum value among the pitches between the plurality of through-vias. Also, a diameter of each of the plurality of through-vias may be measured on a cross-section taken along a central axis of the through-via in the thickness direction, and the minimum diameter may be a minimum value among the diameters of the plurality of through-vias.

When the glass layer 110 is viewed from above, each of the plurality of second through-vias 132 may penetrate the glass layer 110 in a region overlapping cavity C. When viewing the glass layer 110 from above, each of the plurality of third through-vias 133 may penetrate the glass layer 110 in the region spaced apart from the cavity C. Accordingly, an electrical path having a fine pitch and a fine size may be easily provided in one region of the glass layer 110.

The printed circuit board 500A may further include a plurality of third pads 123 disposed on the lower surface of the glass layer 110 and connected to the lower sides of the second through-vias 132, respectively, a plurality of fourth pads 124 disposed on the upper surface of the glass layer 110 and connected to upper sides of the third through-vias 133, respectively, and/or a plurality of fifth pads 125 disposed on the lower surface of the glass layer 110 and connected to lower sides of the third through-vias 133, respectively. Accordingly, electrical connection reliability may be further improved. If desired, a plurality of conductive patterns for various purposes may be formed on the upper surface and/or lower surface of the glass layer 110, in addition to the third to fifth pads 123, 124, and 125.

Hereinafter, components of a printed circuit board 500A according to an example will be described in greater detail with reference to the drawings.

The glass layer 110 may include glass, which is an amorphous solid. The glass may include, for example, pure silicon dioxide (about 100% SiO₂), soda-lime glass, borosilicate glass, aluminosilicate glass, or the like. However, an embodiment thereof is not limited thereto, and alternative glass materials, for example, fluoride glass, phosphate glass, chalcogenide glass, or the like, may also be used as a material thereof. Also, other additives may be further included to form a glass having specific physical properties. Such additives may include calcium carbonate (e.g., lime) and sodium carbonate (e.g., soda), as well as magnesium, calcium, manganese, aluminum, lead, boron, iron, chromium, potassium, sulfur antimony, and carbonates and/or oxides of these elements and other elements. The glass layer 110 may be distinct from organic insulating materials including glass fiber (glass cloth, glass fabric), such as copper clad laminate (CCL), prepreg (PPG), or the like. For example, the glass layer 110 may include a glass panel formed in a relatively large area, such as a glass plate.

Each of the plurality of second and third through-vias 132 and 133 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment thereof is not limited thereto. Each of the plurality of second and third through-vias 132 and 133 may include a filled via or a filled VIA filling a through-hole, for example, a through glass via (TGV) may be included. The plurality of second and third through-vias 132 and 133 may perform various functions depending on a design. For example, the third through-vias may include a ground through-via, a power through-via, and a signal through-via. Each of the plurality of second through-vias 132 may have a substantially tapered shape in cross-sections thereof. Each of the plurality of third through-vias 133 may have a substantially hourglass shape in cross-sections thereof. Each of the plurality of second and third through-vias 132 and 133 may include a sputtering layer as a seed layer, and may substantially fill the via-holes with an electrolytic plating layer. The sputtering layer may be a multilayer structure including a titanium (Ti) layer and a copper (Cu) layer. The electrolytic plating layer may be a copper (Cu) layer formed by electrolytic copper. However, an embodiment thereof is not limited thereto, and the seed layer may form an electroless plating layer, and if desired, both the sputtering layer and the electroless plating layer may be formed as the seed layer.

Each of the plurality of third to fifth pads 123, 124, and 125 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment thereof is not limited thereto. Each of the plurality of third to fifth pads 123, 124, and 125 may perform various functions depending on a design. For example, a signal pad, a power pad, a ground pad, or the like, may be included. Each of the plurality of third to fifth pads 123, 124, and 125 may include a sputtering layer as a seed layer, and may also include an electrolytic plating layer disposed on the seed layer. The sputtering layer may be a multilayer structure including a titanium (Ti) layer and a copper (Cu) layer. The electrolytic plating layer may be a copper (Cu) layer formed by electrolytic copper. However, an embodiment thereof is not limited thereto, and the seed layer may form an electroless plating layer, and if desired, both the sputtering layer and the electroless plating layer may be formed as the seed layer.

The polymer layer 211 may include an organic insulating material. The organic insulating material may include a thermosetting resin such as an epoxy resin, a thermoplastic resin such as a polyimide, or the resins together with an inorganic filler and/or an organic filler. For example, the polymer layer 211 may include an Ajinomoto build-up film (ABF). However, an embodiment thereof is not limited thereto, and the organic insulating material may further include glass fiber (glass cloth, glass fabric). For example, the polymer layer 211 may be copper clad laminate (CCL), prepreg (PPG), or the like. The polymer layer 211 may be a single layer, but if desired, the polymer layer 211 may include a plurality of layers.

Each of the first and second passivation layers 212 and 213 may include a thermosetting resin such as an epoxy resin, a thermoplastic resin such as a polyimide, or inorganic fillers and/or organic fillers together with the resins. For example, each of the first and second passivation layers 212 and 213 may include Ajinomoto build-up film (ABF), solder resist (SR), or the like, but an embodiment thereof is not limited thereto. Each of the first and second passivation layers 212 and 213 may expose a plurality of first and second pads 221 and 222, and, if desired, to this end, each of the layers may have a plurality of openings in the form of solder mask defined (SMD) and/or non-solder mask defined (NSMD), but an embodiment thereof is not limited thereto.

Each of the plurality of first through-vias 231 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment thereof is not limited thereto. Each of the plurality of first through-vias 231 may include a filled via filled VIA filling the through-hole. The plurality of first through-vias 231 may perform various functions depending on a design. For example, the through-vias may include a power through-via, a signal through-via, or the like. Each of the plurality of first through-vias 231 may have a substantially hourglass shape in cross-sections thereof. Each of the plurality of first through-vias 231 may include an electroless plating layer as a seed layer, and an electrolytic plating layer substantially filling the via-hole. The electroless plating layer may include a copper (Cu) layer formed by chemical copper, and the electrolytic plating layer may include a copper (Cu) layer formed by electrolytic copper. However, an embodiment thereof is not limited thereto, and a sputtering layer may be formed as a seed layer, and if desired, both a sputtering layer and an electroless plating layer may be formed as a seed layer.

Each of the plurality of first and second pads 221 and 222 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment thereof is not limited thereto. Each of the plurality of first and second pads 221 and 222 may perform various functions depending on a design. For example, the pads may include a signal pad, a power pad, or the like. Each of the plurality of first and second pads 221 and 222 may include an electroless plating layer as a seed layer, and may include an electrolytic plating layer formed on the seed layer. The electroless plating layer may include a copper (Cu) layer formed by chemical copper, and the electrolytic plating layer may include a copper (Cu) layer formed by electrolytic copper. However, an embodiment thereof is not limited thereto, and a sputtering layer may be formed as the seed layer, and if desired, both a sputtering layer and an electroless plating layer may be formed as the seed layer.

The adhesive layer 250 may include an adhesive. The adhesive may include an epoxy resin, a silicone resin, a polyimide, an acrylic resin, and/or a polyurethane. For example, the adhesive layer 250 may include a die attach film (DAF).

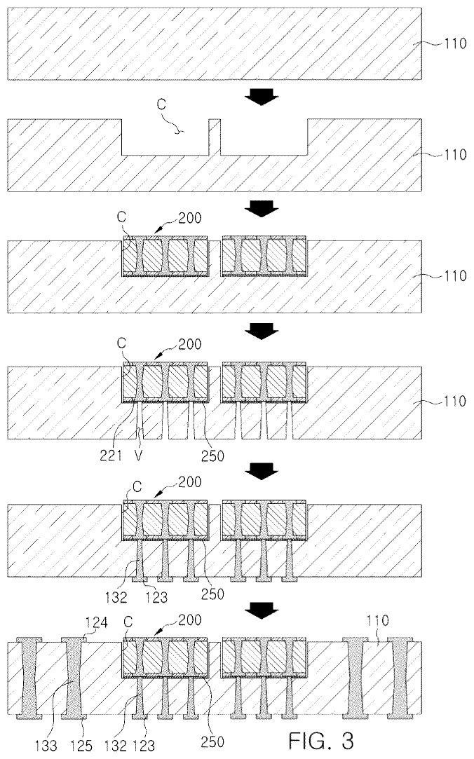

FIG. 3 is a process diagram illustrating the printed circuit board illustrated in FIG. 2.

Referring to the drawing, first, a glass layer 110 may be prepared. The glass layer 110 may be a panel shape having a relatively large area, for example, a glass plate, but an embodiment thereof is not limited thereto. Thereafter, a cavity C having a blind shape and a bottom surface may be formed in the glass layer 110. The cavity C may be formed by a process such as wet etching, dry etching, laser processing, and/or injection molding. The bottom surface of the cavity C may be formed at approximately ½ point of a thickness of the glass layer 110 in the thickness direction. Thereafter, an interconnect unit 200 manufactured by a separate substrate process may be embedded. For example, the interconnect unit 200 may be attached to the bottom surface of the cavity C using an adhesive layer 250. Thereafter, a plurality of via-holes V collectively penetrating the glass layer 110 and the adhesive layer 250, respectively, may be formed in the lower side of the cavity C. The plurality of via-holes V may be formed by laser processing and etching processes. The plurality of first pads 221 may be used as a stopper layer when the plurality of via-holes V are formed. Thereafter, a plurality of second through-vias 132 may be formed by filling the plurality of via-holes V with metal. Also, a plurality of third pads 123 connected to the plurality of second through-vias 132, respectively, may be formed on a lower surface of the glass layer 110. The plurality of second through-vias 132 and the plurality of third pads 123 may be formed by sputtering and electrolytic plating, and if desired, electroless plating may also be used. Thereafter, the plurality of third through-vias 133 and the plurality of fourth and fifth pads 124 and 125 may be formed on the glass layer 110. The via-holes for forming the plurality of third through-vias 133 may also be formed by laser processing and etching processes. The plurality of third through-via 133 and the plurality of fourth and fifth pads 124 and 125 may also be formed by sputtering and electrolytic plating, and if desired, electroless plating may also be used. The plurality of third pads 123 may also be formed when a plurality of fifth pads 125 are formed.

The printed circuit board 500A according to the above-described example may be manufactured through the series of processes, and other descriptions may be substantially the same as described above.

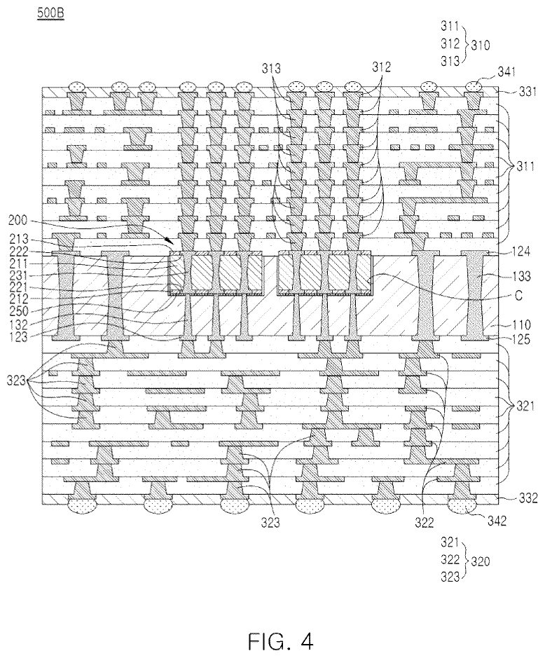

FIG. 4 is a cross-sectional diagram illustrating a modified example of the printed circuit board illustrated in FIG. 2.

Referring to the drawing, a printed circuit board 500B according to the modified example may be implemented as a multilayer printed circuit board structure of a double-sided built-up shape including the printed circuit board 500A according to the above-described example as a core structure. For example, the printed circuit board 500B may include a glass layer 110 as a glass core 110, a first built-up structure 310 disposed on an upper side of the glass core 110, and a second built-up structure 320 disposed on a lower side of the glass core 110. If desired, the printed circuit board 500B may further include a first resist layer 331 disposed on the first built-up structure 310, a second resist layer 332 disposed on the second built-up structure 320, a plurality of first electrical connection metals 341 disposed in first openings of the first resist layer 331, respectively, and/or the plurality of second electrical connection metals 342 disposed in second openings of the second resist layer 332, respectively.

Since the printed circuit board 500B includes the printed circuit board 500A as a core structure as described above, the same technical effects described in relation to the printed circuit board 500A may be included. For example, a body having a relatively large size may be applied, control warpage may be easily performed, and signal and/or power characteristics may be improved by improving signal and/or power paths. Accordingly, the application to a large-area substrate for servers may be easily performed. Also, since signal loss may be reduced, design freedom and design flexibility of the second built-up structure 320 disposed on the lower side of the core structure may improve.

Hereinafter, the components of the printed circuit board 500B according to the modified example will be described in greater detail with reference to the drawings.

The first built-up structure 310 may include a plurality of first insulating layers 311 stacked on an upper surface of the glass layer 110, a plurality of first wiring layers 312 disposed on or in the plurality of first insulating layers 311, respectively, and a plurality of first via layers 313 disposed in the plurality of first insulating layers 311, respectively. The first built-up structure 310, for example, the first insulating layer 311 disposed on a lowermost side of the plurality of first insulating layers 311, may cover at least a portion of the interconnect unit 200 and may fill at least a portion of the cavity C. The second built-up structure 320 may include a plurality of second insulating layers 321 stacked on a lower surface of the glass layer 110, a plurality of second wiring layers 322 disposed on or in the second insulating layer 321, respectively, and a plurality of second via layers 323 disposed in the second insulating layer 321, respectively.

Each of the plurality of first and second insulating layers 311 and 321 may be built-up insulating layers, and may include a thermosetting resin such as an epoxy resin, a thermoplastic resin such as a polyimide, or a resin together with an inorganic filler, an organic filler, and/or glass fiber, glass cloth, or glass fabric. For example, each of the plurality of first and second insulating layers 311 and 321 may be prepreg (PPG), Ajinomoto build-up film (ABF), or the like, but an embodiment thereof is not limited thereto. The plurality of first and second insulating layers 311 and 321 may have substantially the same material, but an embodiment thereof is not limited thereto. The plurality of first and second insulating layers 311 and 321 may have the same number of layers, but an embodiment thereof is not limited thereto.

Each of the plurality of first and second wiring layers 312 and 322 may be a built-up wiring layer, and may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment thereof is not limited thereto. Each of the plurality of first and second wiring layers 312 and 322 may perform various functions depending on a design. For example, a signal pattern, a power pattern, a ground pattern, or the like, may be included. The patterns may have various shapes such as a line, a plane, a pad, or the like. Each of the plurality of first and second wiring layers 312 and 322 may include a seed layer and a plating layer. The seed layer may be formed by electroless plating (e.g., chemical copper), or if desired, by a sputtering process. Alternatively, both may be used. The plating layer may be formed by electrolytic plating (e.g., electrolytic copper). If desired, a copper foil may be further included.

Each of the plurality of first and second via layers 313 and 323 may be a built-up via layer, and may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment thereof is not limited thereto. Each of the plurality of first and second via layers 313 and 323 may include a plurality of connection vias penetrating at least a portion of the plurality of first and second insulating layers 311 and 321, thereby providing electrical connection paths in the plurality of first and second insulating layers 311 and 321, respectively. Each of the plurality of connection vias may perform various functions depending on a design. For example, the vias may include a signal via, a power via, a ground via, or the like. The plurality of connection vias may include filled vias (filled VIAs) in which the via-holes are filled with metal, and may also include a conformal via (conformal VIA) in which the metal is disposed along a wall surface of the via-hole. Each of the plurality of connection vias may have a substantially tapered shape on a cross-section. For example, the plurality of connection vias of the plurality of first via layers 313 may have a tapered shape in which a width of the upper end on a cross-section is wider than a width of a lower end. Also, the plurality of connection vias of the plurality of second via layers 323 may have a tapered shape in which a width of a lower end on a cross-section is wider than a width of the upper end. The plurality of first and second via layers 313 and 323 may include seed layers and plating layers included in the plurality of first and second wiring layers 312 and 322.

The first and second resist layers 331 and 332 may include a thermosetting resin such as an epoxy resin, a thermoplastic resin such as a polyimide, or an inorganic filler and/or an organic filler together with the resin, respectively. For example, the first and second resist layers 331 and 332 may be Ajinomoto build-up film (ABF), solder resist (SR), or the like, but an embodiment thereof is not limited thereto. The plurality of first and second openings may be formed in the first and second resist layers 331 and 332, respectively. In this case, the pad patterns of the first wiring layer 312 on the uppermost side and the second wiring layer 322 on the lowermost side, exposed through the plurality of first and second openings, may be solder mask defined (SMD) and/or non-solder mask defined (NSMD) shapes, but an embodiment thereof is not limited thereto.

The plurality of first and second electrical connection metals 341 and 342 may be connected to the pad patterns of the first wiring layer 312 on the uppermost side and the second wiring layer 322 on the lowermost side, exposed through the plurality of first and second openings, respectively. The plurality of first and second electrical connection metals 341 and 342 may be formed of a low-melting point metal, for example, solders such as tin (Sn)-aluminum (Al)-copper (Cu), but an embodiment thereof is not limited thereto and the material is not particularly limited thereto. Each of the plurality of first and second electrical connection metals 341 and 342 may be a ball, a pin, or the like. The plurality of first and second electrical connection metals 341 and 342 may be formed as multiple layers or an integrated single layer, respectively. When formed as multiple layers, copper pillars and solders may be included, and when formed as a single layer, tin-silver solders may be included, but an embodiment thereof is not limited thereto.

A plurality of semiconductor chips may be mounted on the first resist layer 331 through the plurality of first electrical connection metals 341. The plurality of semiconductor chips may include an integrated circuit (IC) die in which hundreds to millions of elements are integrated into a single chip. The integrated circuit may be, for example, a logic chip such as a central processor (e.g., a CPU), a graphics processor (e.g., a GPU), a field programmable gate array (FPGA), a digital signal processor, an encryption processor, a microprocessor, a microcontroller, an application processor (e.g., an AP), an analog-to-digital converter, an ASIC (application-specific IC), but an embodiment thereof is not limited thereto, and may be a memory chip such as a volatile memory (e.g., DRAM), a non-volatile memory (e.g., ROM), a flash memory, a high bandwidth memory (HBM), or other types such as a photonic integrated circuit (PIC).

Other descriptions may be substantially the same as those described in relation to the printed circuit board 500A and the manufacturing example thereof according to the above-described example.

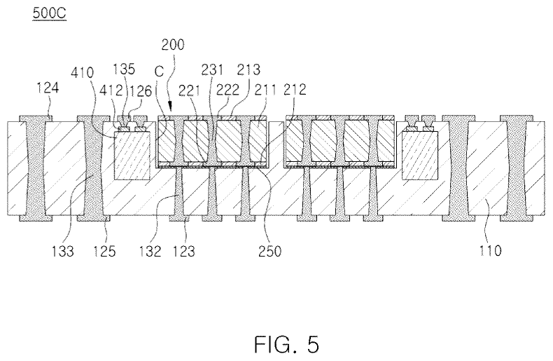

FIG. 5 is a cross-sectional diagram illustrating another example of a printed circuit board according an embodiment.

Referring to the drawings, a printed circuit board 500C according to another example may further include an electronic component 410 embedded in the glass layer 110, differently from the printed circuit board 500A according to the above-described example. The electronic component 410 may be implemented as various types of active components and/or passive components. Accordingly, various techniques required for next-generation semiconductors may be provided. The electronic component 410 may have a plurality of electrode pads 412. The plurality of electrode pads 412 may be connected to a plurality of metal patterns 126, respectively, via a plurality of metal vias 135. The electronic component 410 may be directly embedded in the glass layer 110, but an embodiment thereof is not limited thereto, and may be embedded in a shape in which an additional cavity is formed in the glass layer 110 and disposed in the additionally formed cavity. The plurality of metal vias 135 and the plurality of metal patterns 126 may be formed in the glass layer 110, but an embodiment thereof is not limited thereto, and the vias may additionally be formed in an insulating material filling the formed cavity. The number of electronic components 410 is not limited to any particular example and a necessary number of the electronic components 410 may be embedded in the glass layer 110.

Other descriptions may be substantially the same as those described in relation to the printed circuit board 500A and 500B, and the manufacturing example of the printed circuit board 500A.

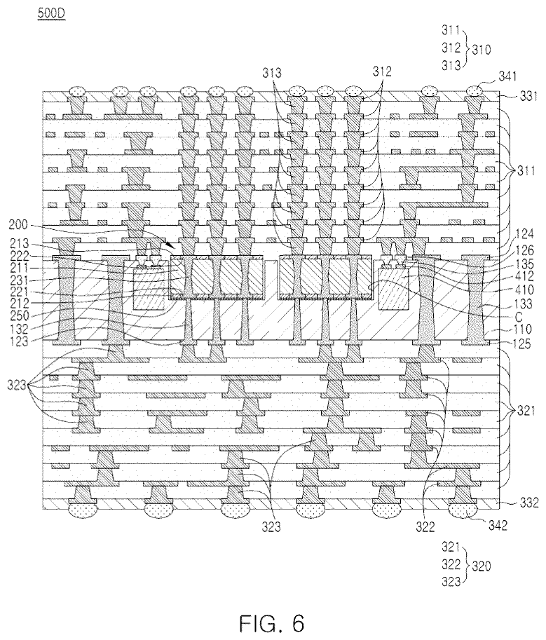

FIG. 6 is a cross-sectional diagram illustrating a modified example of the printed circuit board illustrated in FIG. 5.

Referring to the drawings, a printed circuit board 500D according to the modified example may further include an electronic component 410 embedded in the glass layer 110, differently from the printed circuit board 500B according to the modified example described above. The electronic component 410 may be connected to the first built-up structure 310 and/or the second built-up structure 320 depending on the embedded position. For example, the electronic component 410 may be electrically connected to at least a portion of at least a portion of the plurality of first wiring layers 312 and the plurality of second wiring layers 322 through at least a portion of the plurality of first via layers 313 and the plurality of second via layers 323.

Other descriptions may be substantially the same as those described in the printed circuit boards 500A, 500B, and 500C and the manufacturing examples of the printed circuit board 500A.

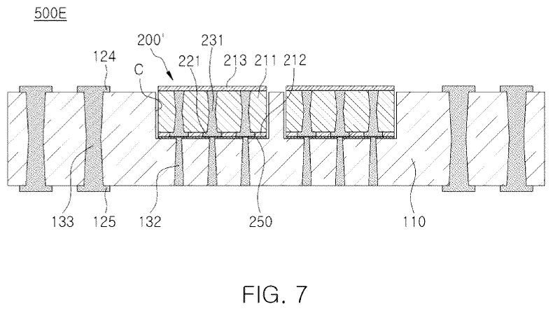

FIG. 7 is a cross-sectional diagram illustrating another example of a printed circuit board according an embodiment.

Referring to the drawings, in a printed circuit board 500E according to another example, an interconnect unit 200′ may not include a plurality of second pads, differently from the printed circuit board 500A according to the above-described example. Also, a plurality of third pads may not be disposed on a lower surface of the glass layer 110. For example, a plurality of second and third pads may not be provided. For example, a landless may be implemented in one region providing an electrical path having a fine pitch and a fine size of the glass layer 110, thereby further improving signal and/or power characteristics.

Other descriptions may be substantially the same as those described in the printed circuit boards 500A, 500B, 500C, and 500D and the manufacturing examples of the printed circuit board 500A.

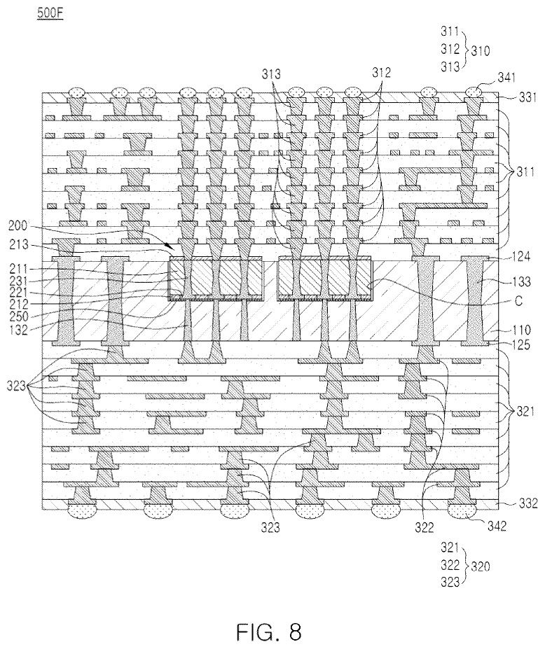

FIG. 8 is a cross-sectional diagram illustrating a modified example of the printed circuit board illustrated in FIG. 7.

Referring to the drawings, in a printed circuit board 500F according to the modified example, an interconnect unit 200′ may not include a plurality of second pads, differently from the printed circuit board 500B according to the modified example described above. Also, a plurality of third pads may not be disposed on a lower surface of the glass layer 110. For example, a plurality of second and third pads may not be provided. Accordingly, among the plurality of first via layers 313, the first via layer 313 disposed on a lowermost side may include a plurality of first connection vias directly connected to upper sides of the plurality of first through-vias 231, respectively. Also, among the plurality of second via layers 323, the second via layer 323 disposed on the uppermost side may include a plurality of second connection vias directly connected to lower sides of the plurality of second through-vias 132, respectively. Each of the plurality of first connection vias may further penetrate a portion of the second passivation layer 213, and accordingly, the plurality of first through-vias may be in direct contact with the plurality of first through-vias 231, respectively.

Other descriptions may be substantially the same as those described in the printed circuit boards 500A, 500B, 500C, 500D, and 500E and the manufacturing example of the printed circuit board 500A.

According to the aforementioned embodiments, a printed circuit board which may have a body having a relatively large, may easily perform control warpage, and may improve signal and/or power characteristics by improving signal and/or power paths may be provided.

A thickness, width, length, pitch, depth, or the like, may be measured using a scanning microscope or optical microscope based on a cross-section of a printed circuit board polished or cut out. The cross-section may be a vertical cross-section or a horizontal cross-section, and each value may be measured based on the required cross-section. When the value is not constant, the value may be determined as an average value of values measured at five arbitrary points. The width of the upper end and/or lower end of the via may be measured on a cross-section taken along the central axis of the via in the thickness direction. The depth of the via may be measured as the distance from the upper end to the lower end of the via on a cross-section taken along the central axis of the substrate in the thickness direction.

In the present disclosure, the term “covering” may include covering entirely and also covering at least a portion, and may also include covering directly and also covering indirectly. Also, the term “filling” may include filling completely and also filling roughly, and may include, for example, the presence of some gaps or voids.

In the present disclosure, process errors, positional deviations, and measurement errors occurring in the manufacturing process may be included. For example, the notion that the line width, distance, thickness, and height are substantially the same may include case in which the elements are completely the same in numerical sense, and also case in which the elements may have similar values. Also, the notion of “having substantially a predetermined shape” may include case of having almost the same shape and also having a similar shape.

In the present disclosure, the same insulating material may indicate that the materials are completely the same insulating material, but insulating materials of the same type are included. Accordingly, the composition of the insulating material may be substantially the same, but the specific composition ratios thereof may be slightly different.

In the present disclosure, “on the cross-section” may indicate the cross-sectional shape when the object is cut vertically, or the cross-sectional shape when the object is viewed from the side. Also, “on a plane” may indicate a plane shape when the object is cut horizontally, or a plane shape when the object is viewed from a top-view or bottom-view.

The terms “lower side,” “lower portion,” “lower surface,” and the like, may be used to refer to a surface formed in a downward direction with reference to a cross-section in the diagrams for ease of description, the terms “upper side,” “upper portion,” “upper surfaces,” and the like, may be used to refer to a surface formed in an upward direction, and the terms “side portion,” “side surface,” and the like, may be used to refer to a surface formed taken in the direction perpendicular to a upper surface and lower surface. The terms, however, may be defined as above for ease of description, and the scope of right of the embodiments is not particularly limited to the above terms.

In the embodiments, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the embodiments.

In the embodiments, the term “embodiment” may not refer to one same embodiment, and may be provided to describe and emphasize different unique features of each embodiment. The above suggested embodiments may be implemented do not exclude the possibilities of combination with features of other embodiments. For example, even though the features described in one embodiment are not described in the other embodiment, the description may be understood as relevant to the other embodiment unless otherwise indicated.

An expression used in the singular encompasses the expression of the plural, unless it has a clearly different meaning in the context.

While the embodiments have been illustrated and described above, it will be apparent to those skilled in the art that modifications and variations could be made without departing from the scope of the present disclosure as defined by the appended claims.

What is claimed is:

1. A printed circuit board, comprising:
a glass layer;
a cavity penetrating a portion of the glass layer from an upper surface of the glass layer;
an interconnect unit including at least a portion disposed in the cavity and including a polymer layer and a plurality of first through-vias each penetrating the polymer layer; and
a plurality of second through-vias each penetrating the glass layer from a lower surface of the glass layer to a bottom surface of the cavity,
wherein the plurality of first through-vias are connected to the plurality of second through-vias, respectively.

2. The printed circuit board of claim 1,
wherein the interconnect unit is attached to a bottom surface of the cavity through an adhesive layer, and
wherein the plurality of second through-vias each further penetrate the adhesive layer.

3. The printed circuit board of claim 2, wherein each of the plurality of second through-vias has a tapered shape in which a width thereof on a cross-section of a lower end is greater than a width on a cross-section of an upper end.

4. The printed circuit board of claim 1,
wherein the interconnect unit further includes a plurality of first pads disposed on a lower side of the polymer layer and connected to lower sides of the plurality of first through-vias, respectively, and
wherein the plurality of second through-vias are connected to the plurality of first through-vias through the plurality of first pads, respectively.

5. The printed circuit board of claim 4, wherein the interconnect unit further include a plurality of second pads disposed on an upper side of the polymer layer and connected to upper sides of the plurality of first through-vias, respectively.

6. The printed circuit board of claim 4, further comprising:
a plurality of third pads disposed on a lower surface of the glass layer and connected to lower sides of the plurality of second through-vias, respectively.

7. The printed circuit board of claim 4, further comprising:
a plurality of third through-vias each penetrating between an upper surface and a lower surface of the glass layer in a region spaced apart from a region in which the cavity is disposed.

8. The printed circuit board of claim 7,
wherein a minimum pitch between the plurality of first through-vias and a minimum pitch between the plurality of second through-vias are smaller than a minimum pitch between the plurality of third through-vias, and
wherein a minimum diameter of each of the plurality of first through-vias and a minimum diameter of each of the plurality of second through-vias are smaller than a minimum diameter of each of the plurality of third through-vias.

9. The printed circuit board of claim 7,
wherein a plurality of fourth pads disposed on an upper surface of the glass layer and connected to upper sides of the plurality of third through-vias, respectively; and
a plurality of fifth pads disposed on a lower surface of the glass layer and connected to lower sides of the plurality of third through-vias, respectively.

10. The printed circuit board of claim 1, further comprising:
a first built-up structure disposed on an upper surface of the glass layer; and
a second built-up structure disposed on a lower surface of the glass layer,
wherein the first built-up structure includes a plurality of first insulating layers stacked on an upper surface of the glass layer, a plurality of first wiring layers disposed on or in the plurality of first insulating layers, respectively, and a plurality of first via layers disposed in the plurality of first insulating layers, respectively,
wherein the second built-up structure includes a plurality of second insulating layers stacked on a lower surface of the glass layer, a plurality of second wiring layers disposed on or in the plurality of second insulating layers, respectively, and a plurality of second via layers disposed in the plurality of second insulating layers, respectively.

11. The printed circuit board of claim 10,
wherein, among the plurality of first via layers, a first via layer disposed on a lowermost side includes a plurality of first connection vias directly connected to upper sides of the plurality of first through-vias, respectively,
wherein, among the plurality of second via layers, a second via layer disposed on an uppermost side includes a plurality of second connection vias directly connected to lower sides of the plurality of second through-vias, respectively,
wherein the interconnect unit further includes first and second passivation layers disposed on a lower surface and an upper surface of the polymer layer, respectively, and
wherein the plurality of first connection vias further penetrate a portion of the second passivation layer, respectively.

12. The printed circuit board of claim 10, further comprising:
an electronic component embedded in the glass layer,
wherein the electronic component is electrically connected to at least a portion of at least one of the plurality of first wiring layers and the plurality of second wiring layers through at least a portion of at least one of the plurality of first via layers and the plurality of second via layers.

13. The printed circuit board of claim 1,
wherein a plurality of cavities and a plurality of interconnect units are provided, and
wherein the plurality of interconnect units are disposed in the plurality of cavities, respectively.

14. A printed circuit board, comprising:
a glass core having a blind cavity;
an interconnect unit having at least a portion disposed in the blind cavity;
a plurality of second through-vias each penetrating the glass core in a region overlapping the blind cavity when the glass core is viewed from above;
a plurality of third through-vias each penetrating the glass core in a region spaced apart from the blind cavity when the glass core is viewed from above;
a first built-up structure disposed on an upper side of the glass core and including a plurality of first wiring layers; and
a second built-up structure disposed on a lower side of the glass core and including a plurality of second wiring layers.

15. The printed circuit board of claim 14,
wherein a minimum pitch between the plurality of second through-vias is smaller than a minimum pitch between the plurality of third through-vias, and
wherein a minimum diameter of each of the plurality of second through-vias is smaller than a minimum diameter of each of the plurality of third through-vias.

16. The printed circuit board of claim 14,
wherein the blind cavity penetrates a portion of the glass core from an upper surface of the glass core toward a lower surface, and
wherein the first built-up structure covers at least a portion of the interconnect unit and fills at least a portion of the blind cavity.

17. The printed circuit board of claim 14,
wherein the interconnect unit includes a plurality of first through-vias,
wherein the plurality of first through-vias are connected to the plurality of second through-vias, respectively,
wherein at least a portion of the plurality of first wiring layers and at least a portion of the plurality of second wiring layers are electrically connected to each other through at least a portion of the plurality of first through-vias and at least a portion of the plurality of second through-vias.

18. A printed circuit board, comprising:
a glass layer having a top surface and a bottom surface;
a cavity penetrating only a portion of the glass layer from the top surface thereof;
an adhesive layer disposed on a bottom surface of the cavity; and
a via extending from the bottom surface of the glass layer into the cavity and penetrating the bottom surface of the cavity and the adhesive layer.

19. The printed circuit board of claim 18, further comprising an interconnect unit at least partially disposed inside the cavity and secured by the adhesive layer.

20. The printed circuit board of claim 19, wherein the interconnect unit comprises a polymer layer and a through-via penetrating the polymer layer.

21. The printed circuit board of claim 20, wherein a position of the through-via within the cavity is aligned with a position of the via such that the through-via and the via are connected to form a conductive path between a top surface of the interconnect unit and the bottom surface of the glass layer.

22. The printed circuit board of claim 18, further comprising a through-glass via penetrating the glass layer between the upper surface and the lower surface of the glass layer, the through-glass via being disposed in a region of the glass layer spaced apart from the cavity.
